(19) United States
(12) Patent Application Publication
(10) Pub. No.: US 2025/0192749 A1
(43) Pub. Date: Jun. 12, 2025

(54) PIEZOELECTRIC-ON-INSULATOR (POI) SUBSTRATE AND METHOD FOR PRODUCING A PIEZOELECTRIC-ON-INSULATOR (POI) SUBSTRATE

(71) Applicant: Soitec, BERNIN (FR)

(72) Inventor: Alexis Drouin, BERNIN (FR)

(21) Appl. No.: 18/843,945

(22) PCT Filed: Mar. 3, 2023
(86) PCT No.: PCT/EP2023/055478

§ 371 Date: Sep. 4, 2024

(30) Foreign Application Priority Data
Mar. 8, 2022 (FR) FR2202034

(51) Int. Cl. H03H 9/02; H03H 3/08

(52) U.S. Cl. CPC H03H 9/02952; H03H 3/08; H03H 9/02574

(57) ABSTRACT

A piezoelectric-on-insulator substrate comprises a support substrate having a first acoustic impedance, a piezoelectric layer, especially a layer of lithium tantalate, lithium niobate, aluminum nitride, lead zirconate titanate, langasite or langatate, a dielectric layer having a second acoustic impedance and sandwiched between the piezoelectric layer and the support substrate, an intermediate layer positioned between the support substrate and the dielectric layer. The intermediate layer is a layer having a variable composition, in particular along its thickness, such that the acoustic impedance of the intermediate layer varies, in particular gradually, between the values of the first and the second acoustic impedances. The present disclosure also relates to a method for producing such a piezoelectric-on-insulator substrate and also to a surface acoustic wave device comprising such a piezoelectric-on-insulator substrate.

### CROSS-REFERENCE TO RELATED APPLICATIONS

This application is a national phase entry under 35 U.S.C. § 371 of International Patent Application PCT/EP2023/055478, filed Mar. 3, 2023, designating the United States of America and published as International Patent Publication WO 2023/169962 A1 on Sep. 14, 2023, which claims the benefit under Article 8 of the Patent Cooperation Treaty of French Patent Application Serial No. FR2202034, filed Mar. 8, 2022.

### TECHNICAL FIELD

The present disclosure relates to a piezoelectric-on-insulator (POI) substrate and to a process for producing such a piezoelectric-on-insulator (POI) substrate.

### BACKGROUND

A piezoelectric-on-insulator (POI) substrate comprises a thin layer of piezoelectric material on a support substrate joined together by a dielectric layer of silicon oxide that provides good adhesion between the layer of piezoelectric material and the support substrate.

Such substrates are used for acoustic wave devices such as sensors or filters. These devices have good performance by virtue of quality values Q and electromechanical coupling coefficients k² that are higher by comparison with other substrates of the prior art.

However, the support substrate material being silicon-based means there is a significant difference between the acoustic impedance of the support substrate and that of the dielectric layer of silicon oxide. This difference in acoustic impedance in the structure of the piezoelectric substrate gives rise to a loss of performance of the acoustic wave device produced on the POI substrate. This is because the difference in acoustic impedance between the support substrate and the dielectric layer of silicon oxide can create parasitic modes in the frequency bands used in acoustic wave devices (SAWs).

An aim of the present disclosure is to overcome the abovementioned drawbacks and, in particular, to design a piezoelectric-on-insulator (POI) substrate having better characteristics for use in acoustic wave devices (SAWs).

### BRIEF SUMMARY

The object of the present disclosure is achieved by a piezoelectric-on-insulator (POI) substrate comprising a support substrate having a first acoustic impedance, a piezoelectric layer, especially a layer of lithium tantalate (LTO), lithium niobate (LNO), aluminum nitride (AIN), lead zirconate titanate (PZT), langasite or langatate, a dielectric layer having a second acoustic impedance and sandwiched between the piezoelectric layer and the support substrate, an intermediate layer positioned between the support substrate and the dielectric layer, characterized in that the intermediate layer is a layer having a variable composition, more particularly along its thickness, such that the acoustic impedance of the intermediate layer varies, especially in a gradual manner, between the values of the first and the second acoustic impedance. Thus, the variation in the acoustic impedance of the intermediate layer makes it possible to gradually reduce the difference in acoustic impedance between the dielectric layer and the support substrate in a piezoelectric-on-insulator (POI) substrate and thus to reduce the losses in performance.

According to one embodiment, the support substrate may be a silicon-based substrate, the dielectric layer is a layer of silicon oxide, and the intermediate layer is a layer of silicon oxynitride SiOₓN_{y} having a variable oxygen composition and/or a variable nitrogen composition. The use of a nitrogen-based intermediate layer situated between the piezoelectric layer and the support substrate makes it possible to reduce the diffusion of lithium or hydrogen into the support substrate while at the same time achieving an intermediate layer having a variable composition.

According to one embodiment, the variation in the oxygen composition and/or in the nitrogen composition of the intermediate layer is a gradual linear or a stepwise variation. The variation of the quantity qt of the silicon oxynitride layer makes it possible to gradually vary the acoustic impedance of the intermediate layer. According to one embodiment, the variable composition of the intermediate silicon oxynitride SiOₓN_{y} layer is defined by the quantity qt=y/(y+x) and may vary along its thickness, more particularly where qt is 0 at the interface with the dielectric layer and qt is at least 0.4 at the interface with the support substrate. The variation of the quantity qt along the thickness of the silicon oxynitride layer makes it possible to gradually reduce the difference in acoustic impedance between the dielectric layer and the support substrate.

According to one embodiment concerned with longitudinal waves, the quantity qt at the interface with the support substrate may be equal to about qt=0.5 since the acoustic impedance Z is equal to 19.4*10⁶ Pa·s/m for a support substrate of the Si (100) type, the quantity x may be equal to about qt=0.68 since Z=21.1*10⁶ Pa·s/m for a support substrate of the Si (110) type, and the quantity qt may be equal to about qt=0.7 since Z=21.6*10⁶ Pa·s/m for a support substrate of the Si (111) type. The variation of the quantity qt at the interface with the support substrate makes it possible to adjust the acoustic impedance to the acoustic impedance of the support substrate according to its crystal orientation.

Depending on the mode of propagation of relevance to the acoustic device, that is to say either a longitudinal propagation wave or a slow or fast shear wave, other optimized values may be determined.

According to one embodiment, the quantity qt of the silicon oxynitride SiOₓN_{y} layer may vary in an increasing manner between the interface with the dielectric layer of the piezoelectric layer and the interface with the support substrate, especially in a stepwise or linear increasing manner. In this way, it is again possible to further reduce the negative effect of differences in acoustic impedance.

According to one embodiment, the piezoelectric-on-insulator (POI) substrate may further comprise a trapping layer on the solid support substrate, especially a polycrystalline silicon-based layer. The presence of a trapping layer on the support substrate makes it possible to improve the piezoelectric-on-insulator substrate while reducing energy loss in the support substrate. The trapping layer being silicon-based, like the support substrate, it is therefore possible to use the intermediate layer in contact with the trapping layer and to reduce the difference in acoustic impedance in the same way as described above.

The object of the present disclosure is also achieved by a process for producing a piezoelectric-on-insulator (POI) substrate comprising the steps of providing a support substrate having a first acoustic impedance, especially a silicon-based substrate, providing a piezoelectric substrate, especially a lithium tantalate (LTO), lithium niobate (LNO), aluminum nitride (AIN), lead zirconate titanate (PZT), langasite or langatate substrate, forming a dielectric layer having a second acoustic impedance on the piezoelectric substrate, especially a layer of silicon oxide, forming an intermediate layer on a free surface of the support substrate, especially a layer based on silicon oxynitride SiOₓN_{y}, the intermediate layer having a variable composition, more particularly along its thickness, such that the acoustic impedance of the intermediate layer varies, especially in a gradual manner, between the values of the first and the second acoustic impedance, and joining the piezoelectric substrate with the dielectric layer with the support substrate with the intermediate layer. Thus, the variation in the acoustic impedance of the intermediate layer makes it possible to gradually reduce the difference in acoustic impedance between the dielectric layer and the support substrate in the piezoelectric-on-insulator substrate and thus to reduce the losses in performance in the piezoelectric-on-insulator (POI) substrate.

According to one embodiment, the joining between the piezoelectric substrate and the support substrate may be achieved between the intermediate layer and the dielectric layer. The intermediate layer being SiOₓN_{y}-based, the joining interface results in the formation of bonds of oxide-oxide type, which are known for being stable.

According to one embodiment, the process may further comprise a step of forming of a dielectric layer on the intermediate layer of the support substrate before the joining step, such that the joining is then achieved between the dielectric layer of the support substrate and the dielectric layer of the piezoelectric substrate. The joining interface of the support substrate with the piezoelectric layer is created at the interface between two dielectric layers and has bonds of the oxide-oxide type, more particularly a bond of the silicon oxide-silicon oxide type, which is a stable bond.

According to one embodiment, the step of forming of the intermediate layer on the support substrate may comprise the formation of a layer based on silicon oxynitride SiOₓN_{y} in which the variable composition qt of the silicon oxynitride SiOₓN_{y} layer defined by the quantity qt₁=y/(y+x) varies along its thickness, more particularly where qt₁ is 0 at the interface with the dielectric layer and qt₁ is at least 0.4 at the interface with the support substrate. Given that the impedance of the intermediate layer varies between a value close to the impedance value of the dielectric layer at the interface with the dielectric layer and a value close to the impedance value of the support substrate, the intermediate layer makes it possible to adjust the acoustic impedances of the different piezoelectric-on-insulator (POI) substrate materials obtained by the process so as to reduce the difference in acoustic impedance of the piezoelectric-on-insulator substrate. The piezoelectric-on-insulator (POI) substrate obtained thus has an acoustic impedance that is better adapted to the use of the substrate in acoustic wave devices, since this results in a reduction in parasitic effects in the frequency bands used in acoustic wave devices.

According to one embodiment, the step of forming of the intermediate layer on the support substrate may comprise the formation of a layer based on silicon oxynitride SiOₓN_{y} in which the quantity qt₂ of the silicon oxynitride SiOₓN_{y} layer defined by qt₂=y/(y+x) varies along its thickness, more particularly where qt₂ is at least 0.4 at the interface with the support substrate, and the process may further include a step of forming of a SiOₓN_{y} layer on the dielectric layer of the piezoelectric substrate before the joining step, the SiOₓN_{y} layer having a quantity qt₃ for the silicon oxynitride SiOₓN_{y} layer defined by qt₃=y/(y+x) that varies along its thickness, more particularly qt₃=0 at the interface with the dielectric layer of the piezoelectric substrate, such that joining is then achieved between the SiOₓN_{y} layer of the support substrate and the SiOₓN_{y} layer of the piezoelectric substrate, where qt₂ is equal to qt₃ at the interface between the SiOₓN_{y} layers of the piezoelectric substrate and the support substrate.

The joining interface of the support substrate with the piezoelectric layer is created at the interface between two intermediate layers based on silicon oxynitride SiOₓN_{y} and has bonds of the oxide-oxide type, which permit a stable bond.

According to one embodiment, the process may further comprise a step of forming of a trapping layer on the support substrate, especially a polycrystalline silicon-based layer. The presence of a trapping layer on the support substrate makes it possible to improve the piezoelectric-on-insulator substrate while reducing energy loss in the support substrate. The trapping layer being silicon-based, like the support substrate, it is therefore possible to use the intermediate layer in contact with the trapping layer and to reduce the difference in acoustic impedance in the same way as described above.

According to one embodiment, the step of forming of the intermediate layer may be carried out by radiofrequency sputtering in a mixed oxygen and nitrogen atmosphere.

The object of the present disclosure is also achieved by an acoustic wave device (SAW) comprising a piezoelectric-on-insulator substrate as described above. Such a SAW device exhibits a reduction in parasitic effects in the frequency bands at which the device is operated through the adjustment of the acoustic impedance between the support substrate and the dielectric layer of the piezoelectric-on-insulator (POI) substrate.

### BRIEF DESCRIPTION OF THE DRAWINGS

The present disclosure and its advantages will be explained in more detail below by way of preferred embodiments and supported, in particular, by the accompanying figures that follow, in which the reference numbers identify characteristics of the present disclosure.

FIG. 1 is a schematic representation of a piezoelectric-on-insulator (POI) substrate according to a first embodiment of the present disclosure.

FIG. 2 shows the variation in the velocity of sound in the intermediate layer as a function of the quantity qt of the composition of the intermediate layer for qt values corresponding to qt=0, qt=0.33, qt=0.50, qt=0.68 and qt=1, according to the first embodiment of the present disclosure.

FIG. 3 depicts the variation in acoustic impedance of the intermediate layer as a function of the quantity qt of the intermediate layer according to the first embodiment of the present disclosure.

FIG. 4 is a schematic representation of a piezoelectric-on-insulator (POI) substrate according to a first variant of the first embodiment of the present disclosure.

FIG. 5A is a schematic representation of a process for producing a piezoelectric-on-insulator (POI) substrate according to a second embodiment of the present disclosure.

FIG. 5B is a schematic representation of a process for producing a piezoelectric-on-insulator (POI) substrate according to a first variant of the second embodiment of the present disclosure.

FIG. 5C is a schematic representation of a process for producing a piezoelectric-on-insulator (POI) substrate according to a second variant of the second embodiment of the present disclosure.

### DETAILED DESCRIPTION

The present disclosure will be described in more detail using advantageous embodiments in an exemplary manner and with reference to the drawings. The embodiments described are simply possible configurations and it should be kept in mind that the individual characteristics as described above can be provided independently of one another or can be omitted entirely in the implementation of the present disclosure.

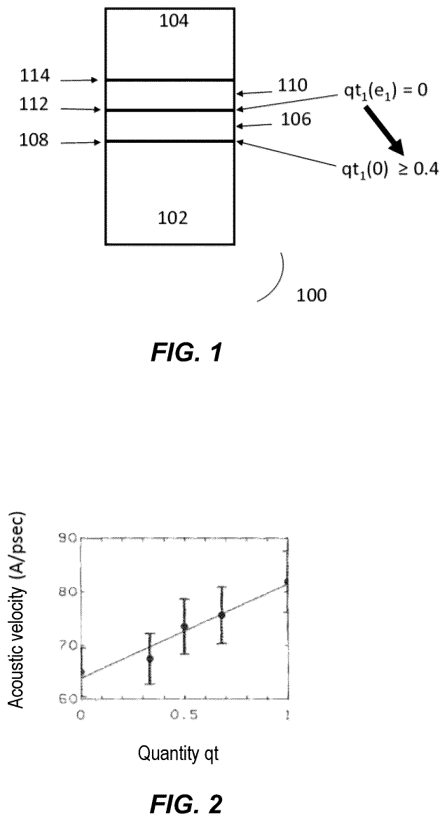

FIG. 1 is a schematic representation of a piezoelectric-on-insulator (POI) substrate according to a first embodiment of the present disclosure.

The piezoelectric-on-insulator (POI) substrate 100 comprises a support substrate 102 joined to a piezoelectric layer 104 via an intermediate layer 106 positioned on the support substrate 102 that is in direct contact with the support substrate 102 at the interface 108 and with a dielectric layer 110 at the interface 112. The dielectric layer 110 is in direct contact with the piezoelectric layer 104 at the interface 114.

The support substrate 102 may be a silicon-based substrate, especially a silicon-based solid substrate. The support substrate 102 may be a crystalline or polycrystalline substrate. The support substrate 102 based on crystalline silicon may have an orientation (111), an orientation (100) or else an orientation (110). The silicon (100) has an acoustic impedance Z equal to 19.4*10⁶ P·a s/m, the silicon (111) has an acoustic impedance of Z=21.6*10⁶ Pa·s/m, the silicon (110) has an acoustic impedance of Z=21.1*10⁶ Pa·s/m.

According to the present disclosure, the dielectric layer 110 is a silicon oxide-based layer having a thickness between 100 nm and 900 nm, more particularly between 200 nm and 700 nm. The dielectric layer 110 has a second acoustic impedance that is different from the first acoustic impedance of the support substrate 102, since the silicon oxide has an acoustic impedance of between 11.5*10⁶ Pa·s/m and 14*10⁶ Pa·s/m, more particularly about 13.7*10⁶ Pa·s/m. In one variant, the dielectric layer 110 may also be a silicon nitride-based layer or a layer comprising a combination of silicon nitride and silicon oxide SiOₓN_{y} in which the amount of nitride in the layer is constant.

The piezoelectric layer 104 is a layer based on a piezoelectric material having a thickness of between 200 nm and 700 nm. The piezoelectric material may, for example, be lithium tantalate (LTO), lithium niobate (LNO), aluminum nitride (AlN), lead zirconate titanate (PZT), langasite or langatate.

The intermediate layer 106 is a layer having a variable composition, more particularly along its thickness e₁. The variation in the composition of the intermediate layer 106 is such that the acoustic impedance of the intermediate layer 106 varies between the values of the first and the second acoustic impedance of the support substrate 102 and of the dielectric layer 110, respectively. The variable acoustic impedance of the intermediate layer 106 makes it possible to limit the influence of the difference in acoustic impedance between the dielectric layer 110 and the support substrate 102 of the POI substrate 100 when gradually passing from the first impedance value to the second impedance value.

According to one embodiment of the present disclosure, the intermediate layer 106 is a layer based on silicon oxynitride SiOₓN_{y}. The thickness e₁ of the intermediate layer 106 is between 100 nm and 1000 nm, more particularly between 200 nm and 1000 nm.

The intermediate layer 106 of silicon oxynitride SiOₓN_{y} according to the present disclosure has a stoichiometry that varies as a function of its thickness e₁ so as to adjust its acoustic impedance. This is because the acoustic impedance of the layer depends on the variation in the amount of oxygen and/or the variation in the amount of nitrogen in the layer.

The values for x and y are set such that a desired or predetermined variation in the acoustic impedance is observed. The amount of oxygen and nitrogen in the intermediate layer 106 depends on the production process used to deposit the layer of SiOₓN_{y}.

According to one embodiment, the intermediate layer is produced as described in Grahn et al.: “Elastic properties of silicon oxynitride films determined by picosecond acoustics,” Applied Physics Letters 53, 2281 (1988), so as to obtain a stoichiometry in the intermediate silicon oxynitride SiOₓN_{y} layer 106 that varies according to qt₁(e₁)=y/(y+x). The SiOₓN_{y} layer is produced by radiofrequency sputtering (RF sputtering) in a mixed oxygen and nitrogen atmosphere. The composition of the SiOₓN_{y} layer is thus controlled by varying the ratio y/(y+x), which corresponds to the amount of nitrogen and the amount of nitrogen and oxygen in the atmosphere during deposition.

The variation in the quantity qt of the silicon oxynitride SiOₓN_{y} layer 106 is a variation in the thickness e₁ of the intermediate layer 106 between the two surfaces of the intermediate layer 106. In this first embodiment, the variation in the quantity qt₁ of the silicon oxynitride SiOₓN_{y} layer 106 is an increasing variation between the interface 112 with the dielectric layer 110 and the interface 108 with the support substrate 102. The variation is, for example, a stepwise increase or is a linear increase.

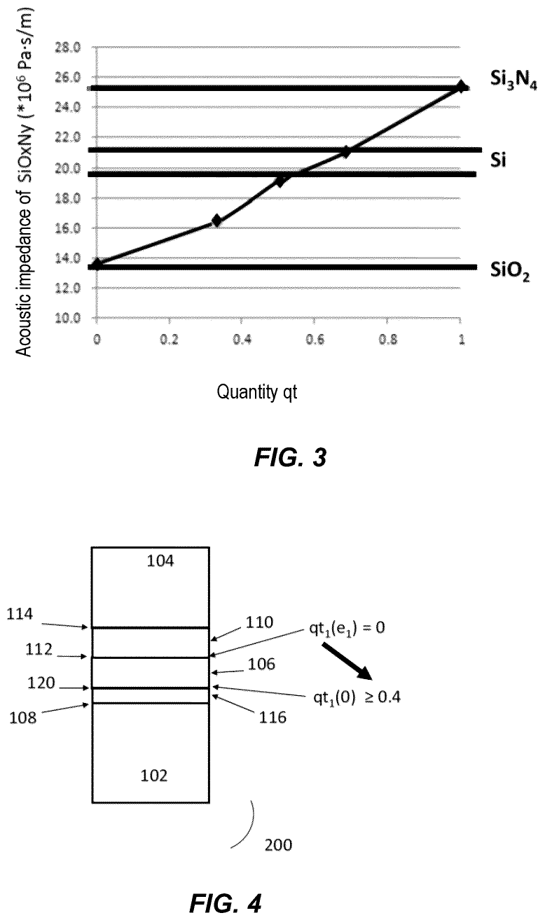

FIG. 2 shows the variation in the velocity of the longitudinal acoustic wave V_{longi} in the intermediate layer 106 as a function of the quantity qt of nitrogen (N) in the intermediate layer 106 for values for the quantity qt in the intermediate layer 106 of 0, 0.33, 0.50, 0.68 and 1. This figure has been published by Grahn et al. “Elastic properties of silicon oxynitride films determined by picosecond acoustics,” Applied Physics Letters 53,2281 (1988).

A linear increase in the velocity of the longitudinal acoustic wave as a function of an increase in the quantity qt of the intermediate layer 106 can also be seen. The line representing the linear variation is an adjustment by the least-squares method at the data points.

Starting from the data in FIG. 2, the acoustic impedance is obtained by calculating the acoustic impedance Z where Z=V_{longi}*density, V_{longi} being the velocity of the longitudinal acoustic wave, according to Grahn et al.: “Elastic properties of silicon oxynitride films determined by picosecond acoustics,” Applied Physics Letters 53, 2281 (1988).

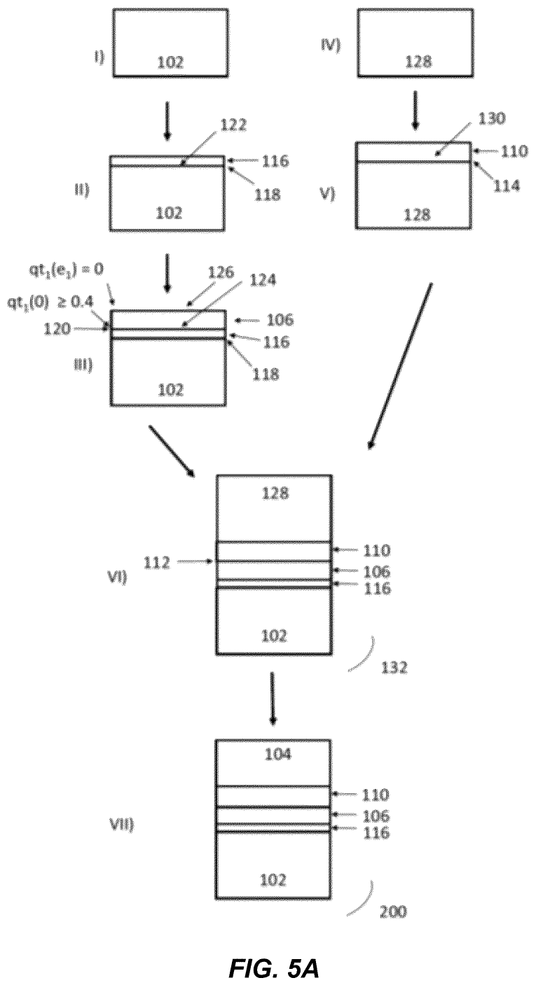

The variation in the acoustic impedance of the SiOₓN_{y} layer as a function of the quantity qt is illustrated in FIG. 3. For a quantity qt equal to 0, the value for the acoustic impedance Z is equal to the value for the acoustic impedance Z of a layer of silicon oxide, this being on the order of 13.7*10⁶ Pa·s/m. As the quantity qt increases, the acoustic impedance of the intermediate layer 106 increases continuously. For a value for quantity qt of between 0.5 and 0.7, the acoustic impedance Z becomes comparable to the acoustic impedance Z of silicon, which is between 19.4*10⁶ Pa·s/m and 21.8*10⁶ Pa·s/m, depending on the crystalline orientation of the silicon. For qt=1, the obtained acoustic impedance Z is that of Si₃N₄, which is on the order of 25.5*10⁶ Pa·s/m. However, this value for the acoustic impedance Z depends on the deposition techniques employed.

Thus, by varying the quantity qt₁ of the intermediate layer 106, a variation in the acoustic impedance value of the intermediate layer 106 can be obtained, a value that can vary between the acoustic impedance value of a layer of Si₃N₄ and that of a layer of silicon oxide. Starting from the values shown in FIG. 3, it is possible to set the value for the quantity qt as a function of the position in the thickness e₁ of the SiOₓN_{y} layer.

On the basis of what is shown in FIG. 3, qt₁(e₁) is set at 0 in the intermediate layer 106 at the interface 112 with the dielectric layer 110. Thereafter, qt₁ increases as a function of the thickness e₁ until reaching a quantity qt₁(e₁=0)≥0.4, more particularly qt₁(e₁=0)=0.7 at the interface with the support substrate. The acoustic impedance of the intermediate layer 106 at the interface 108 with the support substrate 102 (e₁=0) is thus on the order of the first acoustic impedance of the support substrate 102.

The intermediate layer 106 thus makes it possible to reduce the difference in acoustic impedance between the support substrate 102 and the dielectric layer 110 of silicon oxide by its acoustic impedance, which is between the impedance of the support substrate 102 and that of the dielectric layer 110.

In addition, the interface 112 between the dielectric layer 110 and the intermediate layer 106 is an interface that is free of nitrogen (N) and that comprises silicon oxide-silicon oxide bonds, which are known for being stable bonds that improve adhesion.

In addition, given that the intermediate layer 106 is a SiOₓN_{y}-based layer, the presence of nitrogen in the intermediate layer 106 makes it possible to reduce the diffusion of lithium or hydrogen into the support substrate 102.

The piezoelectric-on-insulator (POI) substrate 100 according to the present disclosure thus exhibits improved stability and also improved characteristics for the use thereof in surface acoustic wave devices (SAWs) such as sensors, filters or the like. Reducing the difference in acoustic impedance in the piezoelectric-on-insulator (POI) substrate 100 results in a reduction in undesirable modes in the desired frequency ranges for the operation of surface acoustic wave devices (SAWs).

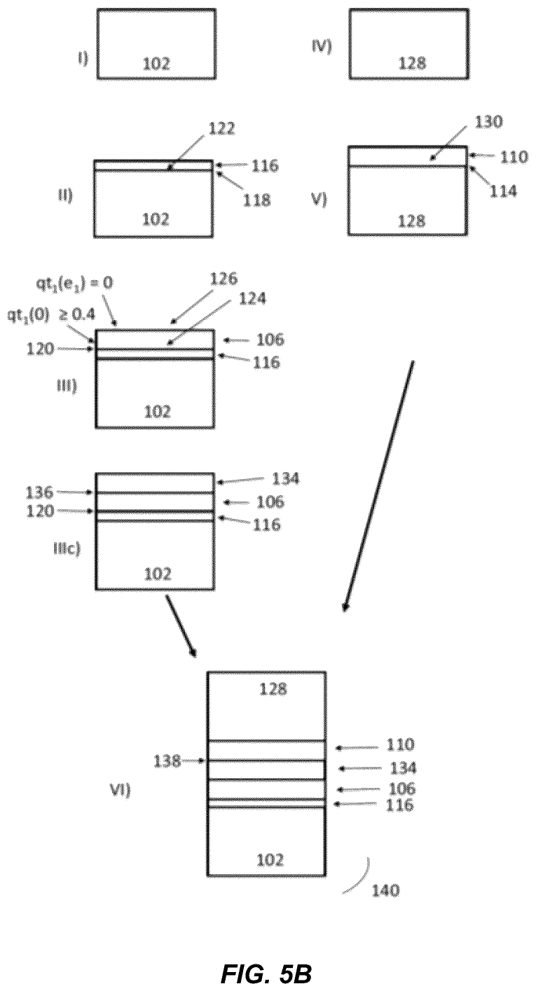

FIG. 4 shows a variant of the first embodiment of the present disclosure. The sole difference between the POI substrate 100 and the POI substrate 200 of the variant is the presence of a trapping layer 116 between the support substrate 102 and the intermediate layer 106. All other characteristics of the POI substrate are the same as those described in FIG. 1. None of the characteristics common to the first embodiment employing the same reference number as above will be described again, but reference is made to their detailed description above.

The trapping layer 116 is in contact with the support substrate 102 at the interface 118 and is also in contact with the intermediate layer 106 at the interface 120. The trapping layer 116 is sandwiched between the support substrate 102 and the intermediate layer 106.

The trapping layer 116 is a layer based on polycrystalline or amorphous or porous silicon, having a thickness of between 200 nm and 5 μm, more particularly between 500 nm and 2 μm. The trapping layer 116 has a third acoustic impedance with a value of about 21*10⁶ Pa·s/m, this value being close to the average acoustic impedance value for the three possible silicon orientations mentioned above.

In this variant, the value of the quantity qt₁ of the variable composition of the silicon oxynitride SiOₓN_{y} layer 106 varies such that the acoustic impedance of the intermediate layer 106 at the interface 120 with the trapping layer 116 is on the order of the third acoustic impedance of the trapping layer 116.

The piezoelectric-on-insulator (POI) substrate 200 has the same advantages as the piezoelectric-on-insulator (POI) substrate 100 described in FIG. 1.

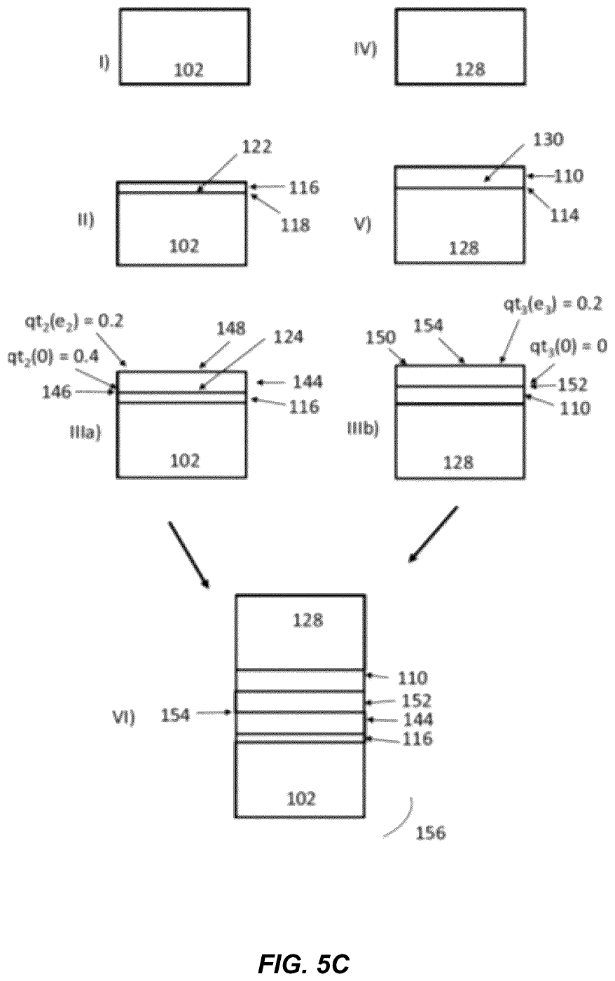

FIG. 5A is a schematic representation of a process for producing a piezoelectric-on-insulator (POI) substrate according to a second embodiment of the present disclosure to obtain a POI substrate as described above in FIGS. 1 and 4 according to the first embodiment of the present disclosure. Elements with the same reference numbers and the properties thereof will not be described again, but reference is made to their description above.

The process for producing a piezoelectric-on-insulator (POI) substrate 200 starts with step I) of providing a support substrate 102, in particular, a silicon-based substrate, more particularly a crystalline or polycrystalline silicon substrate.

According to the present disclosure, step II) involves the forming of the trapping layer 116 on the free surface 122 of the support substrate 102. The forming of the trapping layer 116 may be achieved by a thermal or plasma-assisted growth technique such as PECVD (plasma-enhanced chemical vapor deposition) or PVD (physical vapor deposition).

The trapping layer 116 formed on the support substrate 102 is a layer based on silicon, especially polycrystalline silicon. The thickness of the trapping layer 116 is between 200 nm and 5 μm, more particularly between 500 nm and 2 μm. The trapping layer 116 has a fourth acoustic impedance that may be the same as that of the support substrate 102 or it may be different.

In step III), the intermediate layer 106 is formed on the free surface 124 of the trapping layer 116.

The forming of the intermediate layer 106 may be achieved by a thermal or plasma-assisted growth technique such as LPCVD (low-pressure chemical vapor deposition) or PECVD (plasma-enhanced chemical vapor deposition).

The intermediate layer 106 is a layer based on silicon oxynitride SiOₓN_{y}. The thickness of the intermediate layer 106 is between 100 nm and 1000 nm, more particularly between 200 nm and 1000 nm.

To obtain the variable composition in the intermediate layer 106, the deposition parameters are varied during deposition so as to modify the amount of nitrogen and/or the amount of oxygen in the thickness of the deposited layer in a way that achieves the gradual variation in the composition of the deposited intermediate layer 106 necessary to obtain the desired acoustic impedance at the free upper surface 126 of the deposited intermediate layer 106, as explained above.

The variation in the composition of the deposited layer of silicon oxynitride SiOₓN_{y} is defined by qt=y/(y+x).

The variation in the quantity qti is a decreasing variation between the interface 108 with the support substrate 102 and the free upper surface 126 of the silicon oxynitride SiOₓN_{y} layer 106. The variation is a stepwise decrease or a linear decrease.

At the interface 118 with the support substrate 102, the quantity qt₁ is at least equal to 0.4, more particularly the quantity qt₁ is on the order of 0.7. The acoustic impedance of the intermediate layer 106 at the interface 118 with the support substrate 102 is thus on the order of the first acoustic impedance of the support substrate 102, more particularly it is the same.

At the free upper surface 126 of the intermediate layer 106, which is intended to contact another layer in a subsequent process step, the quantity qt₁ is defined by the acoustic impedance value of the layer that is to be contacted with the free upper surface 126.
In step IV), the piezoelectric substrate 128 is provided.
In step V), the dielectric layer 110 is produced on the free surface 130 of the piezoelectric substrate 128. Before forming the dielectric layer 110, one or more steps of cleaning, brushing or polishing the free surface 130 of the piezoelectric substrate 128 can be carried out to eliminate the presence of particles and dust in order to thus obtain a cleaner free surface 130, which makes it possible to obtain a deposited dielectric layer 110 of better quality.

The forming of the dielectric layer 110 on the free surface 130 of the piezoelectric substrate 128 can be achieved by a thermal or plasma-assisted growth technique such as LPECVD at low pressure and/or low temperature. A thermal treatment may be carried out after deposition of the dielectric layer 110 in order to densify the dielectric layer 110.

According to one variant, surface-treatment steps on the free surface 130 of the piezoelectric substrate 128 may be carried out before the formation of the dielectric layer 110. Examples include a surface activation treatment such as a plasma treatment or an ozone-based treatment.

According to the present disclosure, the dielectric layer 110 is a layer of silicon oxide.

According to the present disclosure, the piezoelectric substrate 128 obtained after step V) is then joined to the support substrate 102 obtained in step III) during a step VI) of joining to form a support substrate-piezoelectric substrate assembly 132. The joining of the piezoelectric substrate 128 on the support substrate 102 is achieved by positioning the intermediate layer 106 in contact with the dielectric layer 110 of the piezoelectric substrate 128 such that the intermediate layer 106 is sandwiched between the dielectric layer 110 of the piezoelectric substrate 128 and the support substrate 102. The intermediate layer 106 is thus in direct contact with the dielectric layer 110 of the piezoelectric substrate 128 at the interface 112.

In this structure, the acoustic impedance of the intermediate layer 106 at the free upper surface 126 is on the order of the acoustic impedance of the dielectric layer 110 of silicon oxide. In addition, the bond between the substrates is created at an interface 112 that is essentially made of the same material on both sides of the interface 112.

Once the two substrates have been joined, a step (not illustrated) of thinning VII) of the piezoelectric substrate 128 may be carried out to obtain a thinner piezoelectric layer 104. For example, the thinning step may be carried out by grinding or by a step of forming a weakened zone in the piezoelectric substrate 128 in such a way as to delineate the piezoelectric layer 104 to be transferred onto the support substrate 102, and fracturing. This step of forming a weakened zone is carried out by implanting atomic or ionic species in the piezoelectric substrate 128. The atomic or ionic implantation may be carried out in such a way that the weakened zone is situated inside the piezoelectric substrate 128 and separates a piezoelectric layer 104 from the remainder of the piezoelectric substrate 128.

This is followed by the performance of a step of fracturing of the support substrate-piezoelectric substrate assembly 132 through an input of thermal and/or mechanical energy at the weakened zone of the piezoelectric substrate 128 so as to obtain a piezoelectric-on-insulator (POI) substrate 200 as illustrated in step VII) of FIG. 5A and in FIG. 4 that has a thinner piezoelectric layer 104 on a support substrate 102.

This method may also be applied to obtain the substrate of FIG. 1.

FIG. 5B is a schematic representation of a process for producing a piezoelectric-on-insulator (POI) substrate according to a first variant of the second embodiment of the present disclosure.

None of the characteristics common to the second embodiment employing the same reference number as above will be described again, but reference is made to their detailed description above.

The sole difference between this process and the one in FIG. 5A consists of the formation IIIc) of a dielectric layer 134 on the free surface of the intermediate layer 106 after step III) of FIG. 5A. The dielectric layer 134 is of the same material as the dielectric layer 110, i.e., silicon oxide. The dielectric layer 134 may be produced in the same way as the dielectric layer 110.

Thus, in the joining step VI), the dielectric layer 134 is contacted with the dielectric layer 110 of the piezoelectric substrate 128 at the interface 138. The assembly 140 is therefore created by molecular adhesion between the two dielectric layers 110 and 134, which are made of the same material, in this case silicon oxide. This achieves an improved bond between the substrates 102 and 128.

All other process steps in this variant are the same as the steps for the process according to the second embodiment described in FIG. 5A for obtaining the (POI) substrate 200.

FIG. 5C is a schematic representation of a process for producing a piezoelectric-on-insulator (POI) substrate according to a second variant of the second embodiment of the present disclosure.

None of the characteristics common to the second embodiment and variants thereof employing the same reference number as above will be described again, but reference is made to their detailed description above.

The sole difference between this process and the one in FIG. 5A consists of the separation of the intermediate layer 106 into two parts. Step III) of FIG. 5A is replaced by two steps, IIIa) and IIIb). A first intermediate layer 144 is formed on the trapping layer 116 in step IIIa). A second intermediate layer 150 is produced on the dielectric layer 110 in step IIIb).

For the first intermediate layer 144 formed on the support substrate 102 and therefore on the trapping layer 116, the first intermediate layer 144 is deposited in such a way in step IIIa) that the quantity qt₂ of the variable composition of the first silicon oxynitride SiOₓN_{y} layer 144 varies along its thickness, where qt₂(0) is at least 0.4 at the interface 146 with the trap-rich layer 116 of the support substrate 102.

The first intermediate layer 144 is deposited such that the quantity qt₂ of the first silicon oxynitride SiOₓN_{y} layer 144 varies in a decreasing manner along the thickness of the first intermediate layer 144.

At the free surface 148 of the first intermediate layer 144, the quantity qt₂ is set at the same value as that of the layer to be contacted in step VII). In this case, for example, qt₂(e₂)=0.2.

For the second intermediate layer 150 formed on the piezoelectric substrate 128, the second intermediate layer 150 is deposited in such a way in step IIIb) that the quantity qt₃ of the variable composition of the second silicon oxynitride SiOₓN_{y} layer 150 varies along its thickness, where qt₃ (e₃=0) is 0 at its interface 152 with the dielectric layer 110.

The second intermediate layer 150 is deposited such that the quantity qt₃ of the second silicon oxynitride SiOₓN_{y} layer 150 varies in an increasing manner along the thickness e₃ of the intermediate layer 150.

At the free surface 154 of the second intermediate layer 150, the quantity qt₃ is the same as the quantity qt₂ at the free surface 148 of the first intermediate layer 144. In this case, therefore, qt₃(e₃)=0.2.

Thus, in the joining step VI), the first intermediate layer 144 of the support substrate 102 is contacted with the second intermediate layer 150 of the piezoelectric substrate 128.

As in the other processes described in relation to FIGS. 5A and 5B, the acoustic impedance varies across the first and second intermediate layers 144 and 150 between the value of the trapping layer 116 and the value of the dielectric layer 110.

The assembly 156 is created by molecular adhesion between the two substrates 102 and 128 at the interface 152 between the first intermediate layer 144 and the second intermediate layer 150. The assembly 156 is therefore created by molecular adhesion between the two intermediate layers 144 and 150, which have essentially the same material at the interface, in this case the silicon oxynitride SiOₓN_{y} layer where qt=0.2. This achieves an improved bond between the substrates 102 and 128.

All other process steps in this variant are the same as the steps for the process according to the second embodiment described in FIG. 5A for obtaining the (POI) substrate 200.

The process according to the second embodiment may also be used to produce the piezoelectric-on-insulator (POI) substrate 100 according to FIG. 1 without the presence of a trap-rich layer 116 on the support substrate 102.

The embodiments described are simply possible configurations and it should be kept in mind that the individual characteristics of the different embodiments can be combined with one another or provided independently of one another.

1. A piezoelectric-on-insulator (POI) substrate, comprising:
a support substrate having a first acoustic impedance;
a piezoelectriclayer;
a dielectric layer having a second acoustic impedance positioned between the piezoelectric layer and the support substrate; and
an intermediate layer positioned between the support substrate and the dielectric layer;
wherein the intermediate layer is a layer having a variable composition along its thickness, such that the acoustic impedance of the intermediate layer varies between the values of the first acoustic impedance and the second acoustic impedance.

2. The piezoelectric-on-insulator substrate of claim 1, wherein the support substrate is a silicon-based substrate, the dielectric layer is a layer of silicon oxide and the intermediate layer is a layer of silicon oxynitride SiOₓN_{y} having a variable oxygen composition and/or a variable nitrogen composition.

3. The piezoelectric-on-insulator substrate of claim 1, wherein a variation in the composition of the intermediate layer is a gradual linear variation or a stepwise variation.

4. The piezoelectric-on-insulator substrate of claim 1, wherein the quantity qt of the variable composition of the silicon oxynitride SiOₓN_{y} layer is defined by qt=y/(y+x) and varies along a thickness of the silicon oxynitride SiOₓN_{y} layer.

5. The piezoelectric-on-insulator substrate of claim 4, wherein the quantity qt at the interface with the support substrate is equal to about 0.5 and the support substrate comprises a (100) Si support substrate.

6. The piezoelectric-on-insulator substrate of claim 4, wherein the quantity qt of the silicon oxynitride SiOₓN_{y} layer varies in an increasing manner between the interface with the dielectric layer of the piezoelectric layer and the interface with the support substrate.

7. The piezoelectric-on-insulator substrate of claim 1, further comprising a trapping layer on the support substrate.

8. A method of producing a piezoelectric-on-insulator substrate according to claim 1, the method comprising:
providing a support substrate having a first acoustic impedance;
providing a piezoelectric substrate;
forming a dielectric layer having a second acoustic impedance on the piezoelectric substrate;
forming an intermediate layer on a free surface of the support substrate, the intermediate layer having a variable composition along a thickness e of the intermediate layer, such that the acoustic impedance of the intermediate layer varies between the values of the first acoustic impedance and the second acoustic impedance; and
joining the piezoelectric substrate with the dielectric layer with the support substrate with the intermediate layer.

9. The method of claim 8, wherein the joining of the piezoelectric substrate and the support substrate comprises bonding the intermediate layer directly to the dielectric layer.

10. The method of claim 8, further comprising forming a dielectric layer on the intermediate layer of the support substrate before the joining of the piezoelectric substrate with the support substrate, the joining comprising bonding the dielectric layer of the support substrate directly to the dielectric layer of the piezoelectric substrate.

11. The method of claim 8, wherein the forming of the intermediate layer on the free surface of the support substrate comprises forming a layer based on silicon oxynitride SiOₓN_{y} in which the amount of nitrogen in relation to the oxygen in the silicon oxynitride SiOₓN_{y} layer defined by qt₁=y/(y+x) varies along its a thickness e₁ of the intermediate layer.

12. The method of claim 8, wherein the forming of the intermediate layer on the free surface of the support substrate comprises forming a layer based on silicon oxynitride SiOₓN_{y} in which the quantity qt₂ of the silicon oxynitride SiOₓN_{y} layer defined by qt₂=y/(y+x) varies along a thickness e₂ of the layer based on silicon oxynitride SiOₓN_{y}, and the method further comprises forming a SiOₓN_{y} layer on the dielectric layer of the piezoelectric substrate before the joining, the SiOₓN_{y} layer having a quantity qt₃ for the SiOₓN_{y} layer defined by qt₃=y/(y+x) that varies along a thickness e₃ of the SiOₓN_{y} layer, the joining comprising bonding the SiOₓN_{y} layer of the support substrate and the SiOₓN_{y} layer of the piezoelectric substrate, where qt₂ is equal to qt₃ at an interface between the SiOₓN_{y} layer of the piezoelectric substrate and the SiOₓN_{y} layer of the support substrate.

13. The method of claim 8, further comprising forming a trapping layer on the support substrate.

14. The method of claim 8, wherein the forming of the intermediate layer comprises radiofrequency sputtering in a mixed oxygen and nitrogen atmosphere.

15. A surface acoustic wave device (SAW) comprising a piezoelectric-on-insulator substrate according to claim 1.

16. The piezoelectric-on-insulator substrate of claim 1, wherein the piezoelectric layer comprises a layer of lithium tantalate (LTO), lithium niobate (LNO), aluminium nitride (AlN), lead zirconate titanate (PZT), langasite or langatate.

17. The piezoelectric-on-insulator substrate of claim 1, wherein the acoustic impedance of the intermediate layer varies in a gradual manner between the values of the first acoustic impedance and the second acoustic impedance.

18. The piezoelectric-on-insulator substrate of claim 1, wherein qt is 0 at the interface with the dielectric layer and qt is at least 0.4 at the interface with the support substrate.

19. The piezoelectric-on-insulator substrate of claim 4, wherein the quantity qt at the interface with the support substrate is equal to about 0.68 and the support substrate comprises a (110) Si support substrate.

20. The piezoelectric-on-insulator substrate of claim 4, wherein the quantity qt at the interface with the support substrate is equal to about 0.7 and the support substrate comprises a (111) Si support substrate.
